(19) United States
(12) Patent Application Publication
(10) Pub. No.: US 2022/0406924 A1
(43) Pub. Date: Dec. 22, 2022

(54) SEMICONDUCTOR DEVICE

(71) Applicant: SUMITOMO ELECTRIC INDUSTRIES, LTD., Osaka (JP)

(72) Inventor: Kenta SUGAWARA, Osaka-shi (JP)

(73) Assignee: SUMITOMO ELECTRIC INDUSTRIES, LTD., Osaka (JP)

(21) Appl. No.: 17/718,398

(22) Filed: Apr. 12, 2022

(30) Foreign Application Priority Data
Jun. 21, 2021 (JP) 2021-102606

(51) Int. Cl. H01L 29/778; H01L 29/20; H01L 29/205; H01L 29/423; H01L 29/40; H01L 29/66

(52) U.S. Cl. CPC H01L 29/7785; H01L 29/2003; H01L 29/205; H01L 29/42316; H01L 29/401; H01L 29/66462

(57) ABSTRACT

A semiconductor device includes a substrate, a semiconductor layer that is provided on the substrate and includes channel layers that are stacked, a source electrode and a drain electrode that are electrically connected to the channel layers, and gate electrodes that are provided between the source electrode and the drain electrode, are arranged in a direction intersecting with a direction from the source electrode to the drain electrode, and are embedded in the semiconductor layer so as to extend from a top face of the semiconductor layer to at least a channel layer closest to the substrate, wherein a width between two adjacent gate electrodes of the gate electrodes in a channel layer farther from the substrate of two channel layers of the channel layers, is narrower than a width between the two adjacent gate electrodes in a channel layer closer to the substrate of the two channel layers.

### CROSS-REFERENCE TO RELATED APPLICATION

This application is based upon and claims the benefit of priority of the prior Japanese Patent Application No. 2021-102606, filed on Jun. 21, 2021, the entire contents of which are incorporated herein by reference.

### BACKGROUND

### (i) Technical Field

The present disclosure relates to a semiconductor device.

### (ii) Related Art

There has been known a field effect transistor (FET) having channel layers, which are stacked on a substrate, and gates, which are arranged so as to intersect with the direction in which carriers in the channel layers conduct and are embedded to the channel layer, as disclosed in, for example, U.S. Pat. No. 10,388,746 and 2019 IEEE/MTT-S International Microwave Symposium p. 1133-1135. Note that the technique related to the present disclosure is also disclosed in U.S. Pat. No. 10,249,711.

### SUMMARY

In such multichannel FETs, the heat is released from the substrate. Therefore, it is difficult to release, from the substrate, the heat generated in the channel layer far from the substrate. As a result, the temperature of the channel layer far from the substrate increases.

According to an aspect of the present disclosure, there is provided a semiconductor device including: a substrate; a semiconductor layer that is provided on the substrate and includes channel layers that are stacked; a source electrode and a drain electrode that are electrically connected to the channel layers; and gate electrodes that are provided between the source electrode and the drain electrode, are arranged in a direction intersecting with a direction from the source electrode to the drain electrode, and are embedded in the semiconductor layer so as to extend from a top face of the semiconductor layer to at least a channel layer closest to the substrate, wherein a width between two adjacent gate electrodes of the gate electrodes in a channel layer farther from the substrate of two channel layers of the channel layers, is narrower than a width between the two adjacent gate electrodes in a channel layer closer to the substrate of the two channel layers.

### BRIEF DESCRIPTION OF THE DRAWINGS

FIG. 1 is a plan view of a semiconductor device in accordance with a first embodiment;

FIG. 2 is a cross-sectional view taken along line A-A in FIG. 1;

FIG. 3 is a cross-sectional view taken along line B-B in FIG. 1;

FIG. 4A is a cross-sectional view (No. 1) illustrating a manufacturing method of the first embodiment;

FIG. 4B is a cross-sectional view (No. 2) illustrating the manufacturing method of the first embodiment;

FIG. 4C is a cross-sectional view (No. 3) illustrating the manufacturing method of the first embodiment;

FIG. 4D is a cross-sectional view (No. 4) illustrating the manufacturing method of the first embodiment;

FIG. 5 is a cross-sectional view of the semiconductor device in accordance with the first embodiment;

FIG. 6 schematically illustrates transconductance in each channel in the first embodiment;

FIG. 7 is a cross-sectional view of a semiconductor device in accordance with a first variation of the first embodiment;

FIG. 8 is a cross-sectional view of a semiconductor device in accordance with a second variation of the first embodiment;

FIG. 9 is a cross-sectional view of a semiconductor device in accordance with a third variation of the first embodiment; and

FIG. 10 is a cross-sectional view of a semiconductor device in accordance with a fourth variation of the first embodiment.

### DETAILED DESCRIPTION

### Description of Embodiments of the Present Disclosure

First, details of embodiments of the present disclosure will be described as listed below. An embodiment of the present disclosure is (1) a semiconductor device including: a substrate; a semiconductor layer that is provided on the substrate and includes channel layers that are stacked; a source electrode and a drain electrode that are electrically connected to the channel layers; and gate electrodes that are provided between the source electrode and the drain electrode, are arranged in a direction intersecting with a direction from the source electrode to the drain electrode, and are embedded in the semiconductor layer so as to extend from a top face of the semiconductor layer to at least a channel layer closest to the substrate, wherein a width between two adjacent gate electrodes of the gate electrodes in a channel layer farther from the substrate of two channel layers of the channel layers, is narrower than a width between the two adjacent gate electrodes in a channel layer closer to the substrate of the two channel layers.

(2) The channel layers preferably include three or more channel layers, and in each pair of adjacent channel layers of the channel layers, a width between the two adjacent gate electrodes in a channel layer farther from the substrate is preferably equal to or less than a width between the two adjacent gate electrodes in a channel layer closer to the substrate.

(3) The channel layers preferably include three or more channel layers, and in each pair of adjacent channel layers of the channel layers, a width between the two adjacent gate electrodes in a channel layer farther from the substrate is preferably narrower than a width between the two adjacent gate electrodes in a channel layer closer to the substrate.

(4) Side faces of the two adjacent gate electrodes are preferably inclined against a stack direction of the channel layers.

(5) A width between the two adjacent gate electrodes in a channel layer farthest from the substrate among the channel layers is preferably equal to or less than 0.9 times a width between the two adjacent gate electrodes in a channel layer closest to the substrate among the channel layers.

(6) The semiconductor layer preferably has an energy of a bottom of a conduction band higher than energies of bottoms of conduction bands of the channel layers, and includes barrier layers stacked on the channel layers, respectively.

(7) The gate electrodes are preferably in Schottky junction with the semiconductor layer.

(8) The semiconductor device preferably further includes an insulating film provided between the gate electrodes and the semiconductor layer.

### Details of Embodiments of the Present Disclosure

The following describes a specific example of a semiconductor device in accordance with an embodiment of the present disclosure, with reference to the drawings. It should be noted that the present disclosure is not limited to these examples but is shown by the claims, and it is intended that all modifications are included in the equivalents of the claims and the scope of the claims.

### First Embodiment

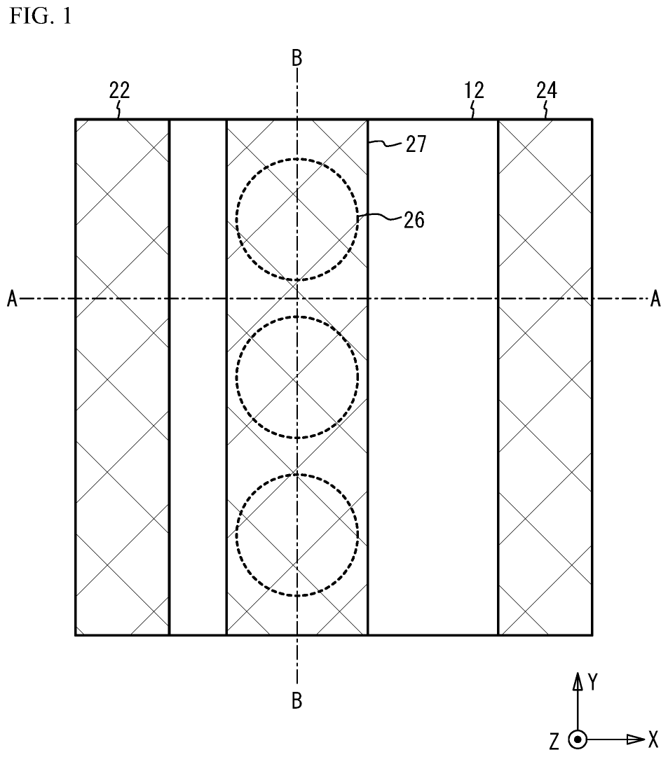

As illustrated in FIG. 1 to FIG. 3, a semiconductor layer 12 is provided on a substrate 10. A buffer layer 13, semiconductor layers 12a, 12b, 12c, and 12d, and a cap layer 18 are stacked in this order from the substrate 10 side to form the semiconductor layer 12. The semiconductor layer 12a has a channel layer 14a and a barrier layer 16a provided on the channel layer 14a, the semiconductor layer 12b has a channel layer 14b and a barrier layer 16b provided on the channel layer 14b, the semiconductor layer 12c has a channel layer 14c and a barrier layer 16c provided on the channel layer 14c, and the semiconductor layer 12d has a channel layer 14d and a barrier layer 16d provided on the channel layer 14d. The channel layers 14a to 14d have 2DEGs 17a to 17d formed therein, respectively.

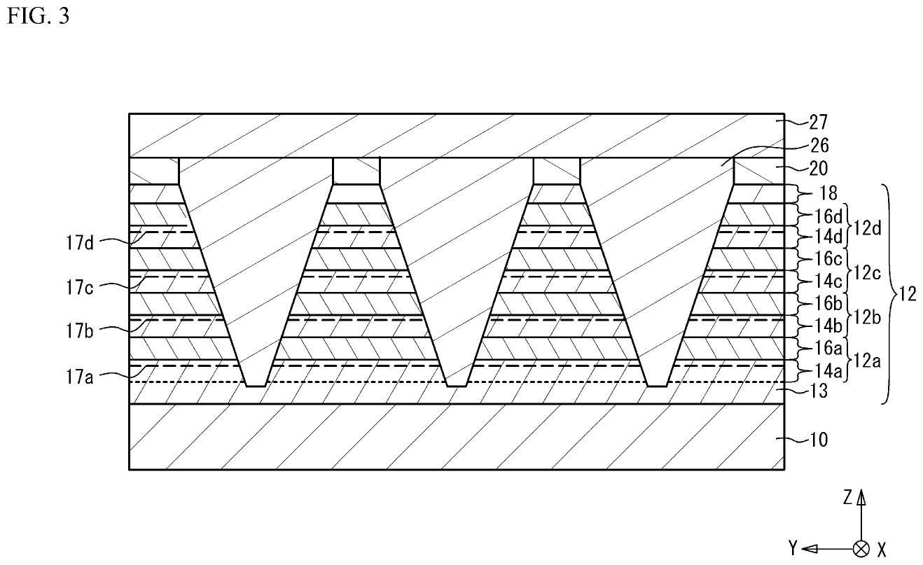

A source electrode 22 and a drain electrode 24 reaching from the top face of the semiconductor layer 12 to the buffer layer 13 are provided in the semiconductor layer 12. The source electrode 22 and the drain electrode 24 are electrically connected to the 2DEGs 17a to 17d in the channel layers 14a to 14d. An insulating film 20 is provided on the semiconductor layer 12 between the source electrode 22 and the drain electrode 24. Gate electrodes 26 are arranged in the Y direction (the direction intersecting with the direction from the source electrode 22 to the drain electrode 24) between the source electrode 22 and the drain electrode 24, and are embedded in the semiconductor layer 12 so as to extend from the top face of the semiconductor layer 12 to at least the channel layer 14a closest to the substrate 10. The planar shape of the gate electrode 26 is a circular shape, and the cross-sectional shape of the gate electrode 26 is a trapezoidal shape having a lower base shorter than an upper base. The planar shape of the gate electrode 26 may be a rectangular shape, an elliptical shape, or other shapes. Since the side face of the gate electrode 26 is inclined, the respective widths between the adjacent gate electrodes 26 in the Y direction in the channel layers 14a to 14d decrease at farther distances from the substrate 10. The gate electrode 26 controls the electric potential of the semiconductor layer 12. A wiring layer 27 is provided on the insulating film 20. The insulating film 20 has openings having the same planar shape as the gate electrode 26 in a plan view illustrated in FIG. 1. As illustrated in the cross-sectional view of FIG. 3, the gate electrodes 26 are coupled to the wiring layer through the respective openings. As a result, the gate electrodes 26 have substantially the same electric potential. The current flowing between the source electrode 22 and the drain electrode 24 can be controlled using the electric potential applied to the wiring layer 27.

The substrate 10 is, for example, a SiC substrate, a sapphire substrate, or a GaN substrate. The top face of the substrate 10 is, for example, a (0001) face. The semiconductor layer 12 is, for example, a nitride semiconductor layer. The buffer layer 13 and the channel layers 14a to 14d are, for example, GaN layers. The barrier layers 16a to 16d are, for example, AlGaN layers or InAlGaN layers. The cap layer 18 is, for example, a GaN layer. A spacer layer may be provided between each of the channel layers 14a to 14d and the corresponding one of the barrier layers 16a to 16d. The spacer layer is, for example, an AlN layer. A nucleation layer such as an AlN layer or the like may be formed between the substrate 10 and the buffer layer 13. The buffer layer 13 and the channel layer 14a are included in a single GaN layer. The lower part of the GaN layer serves as the buffer layer 13, and the upper part of the GaN layer serves as the channel layer 14a. Therefore, the GaN layer will be described as the buffer layer 13 and the channel layer 14a for convenience sake. No intentional dopants are added to the buffer layer 13, the channel layers 14a to 14d, the barrier layers 16a to 16d, and the cap layer 18, and the dopant concentration is, for example, 1×10¹⁶ cm⁻³ or less. The barrier layers 16a to 16d may contain no dopants intentionally, but dopants may be added to the barrier layers 16a to 16d intentionally. The dopant concentration in each of the barrier layers 16a to 16d may be, for example, 1×10¹⁶ cm³ or greater. The semiconductor layer 12 may be a GaAs-based semiconductor instead of a GaN-based semiconductor.

The band gaps of the channel layers 14a to 14d are less than the band gaps of the barrier layers 16a to 16d, respectively, and the energies of the bottoms of the conduction bands of the channel layers 14a to 14d are lower than the energies of the bottoms of the conduction bands of the barrier layers 16a to 16d, respectively. The two dimensional electron gases (2DEGs) 17a to 17d corresponding to the differences between the polarizations of the channel layers 14a to 14d and the polarizations of the barrier layers 16a to 16d are generated on the boundary faces between the channel layers 14a to 14d and the barrier layers 16a to 16d, respectively. The 2DEGs 17a to 17d generated in the channel layers 14a to 14d, respectively, contribute to the conduction of electrons.

The source electrode 22 and the drain electrode 24 are formed of, for example, a titanium film and an aluminum film that are stacked in this order from the semiconductor layer 12 side. A source region and a drain region that are coupled to the channel layers 14a to 14d and have a dopant concentration of 1×10¹⁹ cm⁻³ or greater may be provided in the semiconductor layer 12, and the source electrode 22 and the drain electrode 24 may be provided on the source region and the drain region, respectively. The gate electrodes 26 and the wiring layer 27 are formed of, for example, a nickel film and a gold film that are stacked in this order from the semiconductor layer 12 side. The insulating film 20 is, for example, a silicon nitride film, a silicon oxide film, or a silicon oxynitride film.

A depletion layer depending on the gate voltage applied to the gate electrode 26 is formed in the periphery of the gate electrode 26. The 2DEGs 17a to 17d are hardly formed in the channel layers 14a to 14d in the depletion layer. The 2DEGs 17a to 17d are formed in the channel layers 14a to 14d in the sections other than the depletion layer. The current flowing between the source electrode 22 and the drain electrode 24 can be controlled by the electric potential applied to the gate electrode 26. Manufacturing Method of the First Embodiment

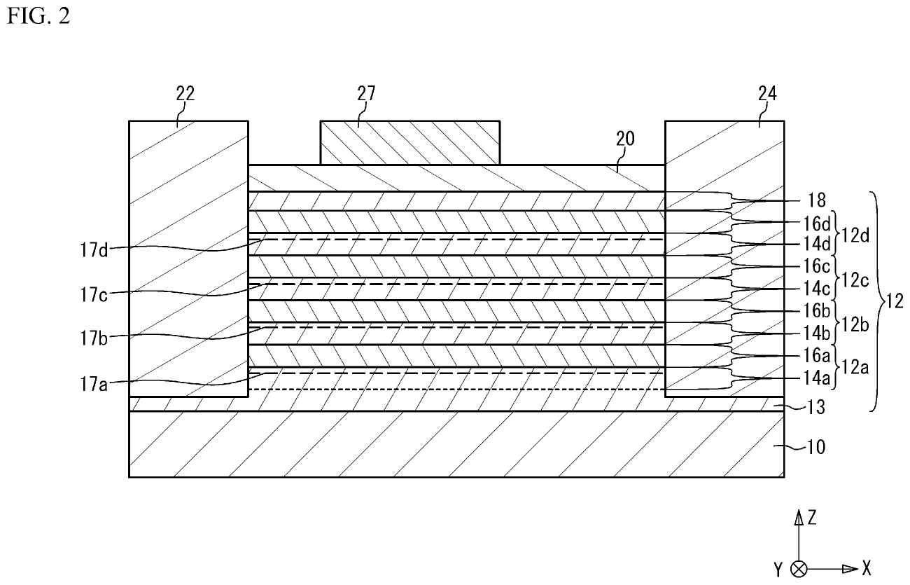

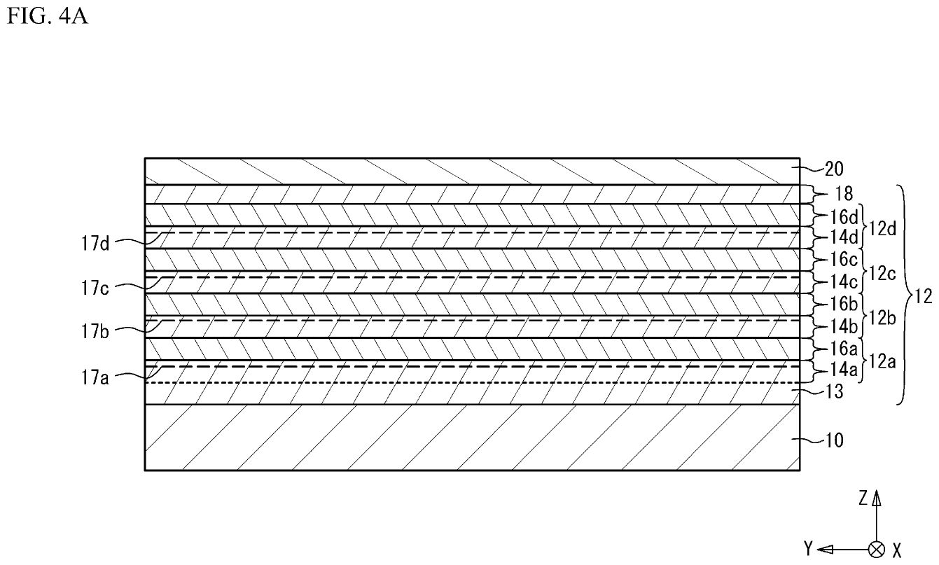

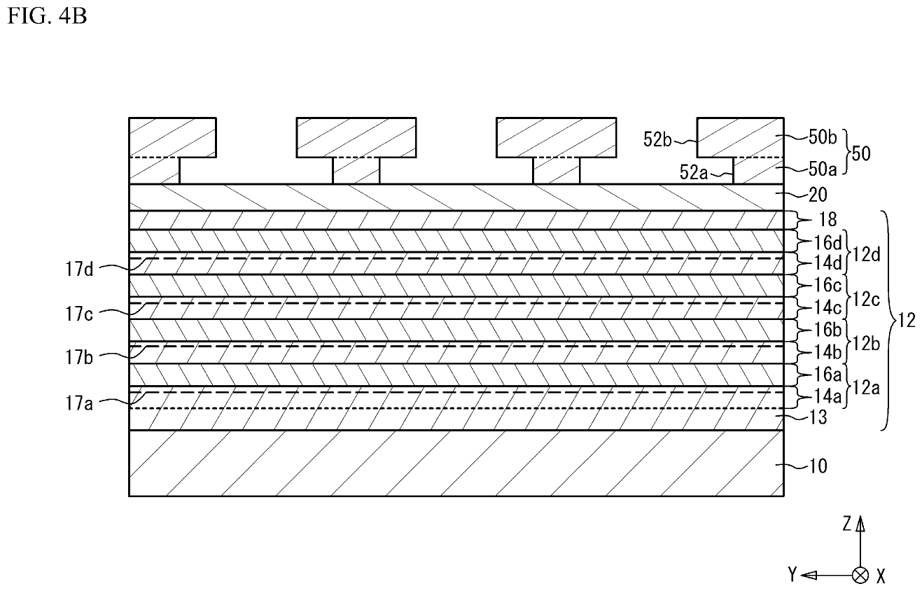

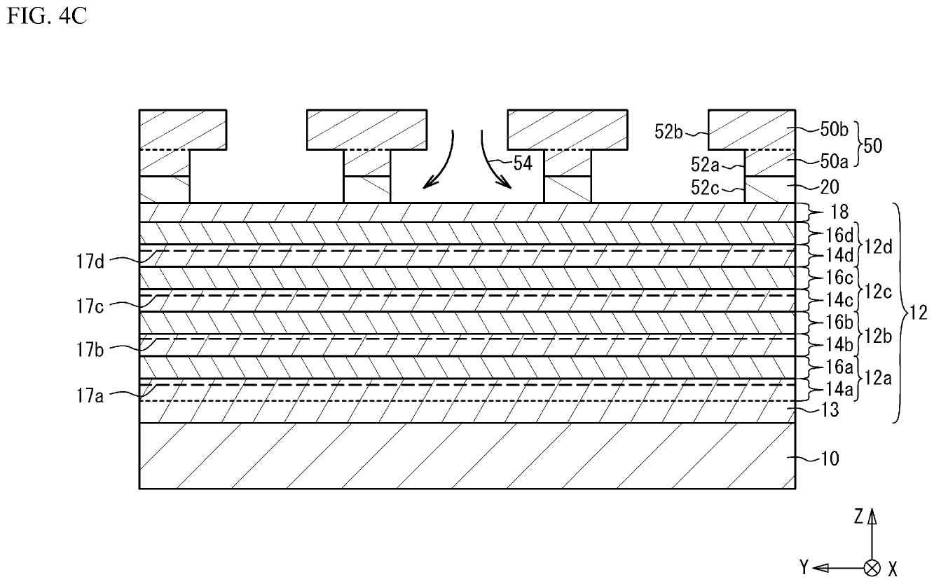

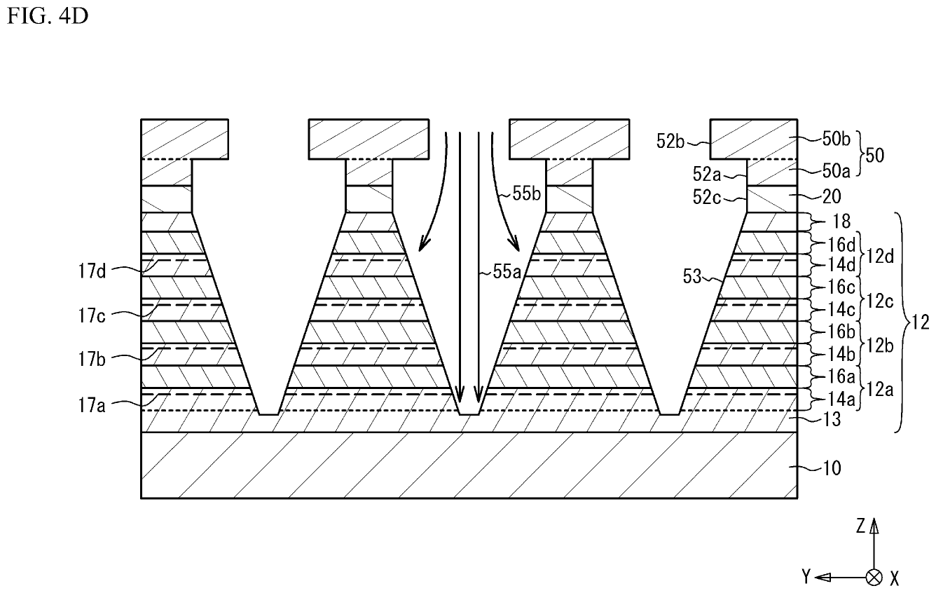

FIG. 4A to FIG. 4D are cross-sectional views illustrating a manufacturing method of the first embodiment. As illustrated in FIG. 4A, the semiconductor layer 12 is formed on the substrate 10 using, for example, the metal organic chemical vapor deposition (MOCVD) method. The layer structure of the semiconductor layer 12 is the same as the layer structure illustrated in FIG. 2 and FIG. 3. The insulating film 20 is formed on the semiconductor layer 12 using, for example, the chemical vapor deposition (CVD) method.

As illustrated in FIG. 4B, a photoresist 50 is applied to the insulating film 20. The photoresist 50 is, for example, a two-layer resist in which a photoresist 50b is provided on a photoresist 50a. The photoresist 50a has a higher photosensitivity than the photoresist 50b. This causes openings 52a formed in the photoresist 50a by exposure and development to be larger than openings 52b formed in the photoresist 50b.

As illustrated in FIG. 4C, the insulating film 20 is dry-etched using the photoresist 50 as a mask. Used as the etching gas is a fluorine-based gas such as CF₄, CHF₃, SF₆, or CH₂F₆, which produces fluorine ions and radicals. As a result, the insulating layer such as a silicon nitride layer is etched, but the semiconductor layer 12 is hardly etched. The etching conditions are set so that the radicals reach the end of the photoresist 50a as indicated by arrows 54. This causes openings 52c having the same size as the opening 52a to be formed in the insulating film 20. The side face of the opening 52c may be inclined.

As illustrated in FIG. 4D, the semiconductor layer 12 is dry etched using the photoresist 50 and the insulating film 20 as a mask. Used as the etching gas is a chlorine-based gas such as Cl₂, BCl₃, or SiCl₄, which produces chlorine ions and radicals. As a result, the semiconductor layer 12 is etched, but the insulating film 20 is hardly etched. As indicated by arrows 55a, the semiconductor layer 12 is etched in the -Z direction by ions passing through the openings 52b and entering perpendicularly to the -Z direction. As indicated by arrows 55b, the semiconductor layer 12 is etched in the oblique direction by radicals coming around in the planar direction. As described above, by adjusting the etching conditions, a groove 53 having a side face with a desired inclined angle is formed using the combination of the etching in the vertical direction and the etching in the oblique direction.

Thereafter, the gate electrodes 26 are formed in the respective grooves 53, and the wiring layer 27 is formed on the insulating film 20. The gate electrodes 26 and the wiring layer 27 are formed using, for example, the vacuum evaporation method and the liftoff technique, or using the sputtering method and the etching method. The grooves are formed in the insulating film 20 and the semiconductor layer 12, and the source electrode 22 and the drain electrode 24 are formed in the respective grooves. Through the above process, the semiconductor device in accordance with the first embodiment is formed.

In the case that the side face of the groove 53 is vertical (parallel to the Z direction), when the gate electrodes 26 are formed using the physical vapor deposition method such as the vacuum evaporation method, the sputtering method, or other methods, the coverage of the gate electrode 26 on the side face of the groove 53 may be poor and the gate electrode 26 may be in no contact with the side face of the groove 53. In the first embodiment, the side face of the groove 53 is tapered so that the width of the top face of the groove 53 is greater than the width of the bottom face of the groove 53. This improves the coverage of the gate electrode 26 on the side face of the groove 53.

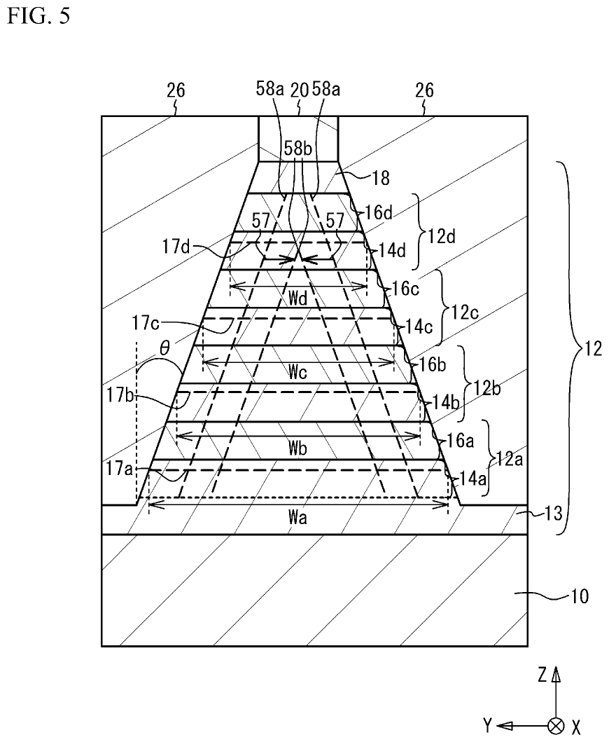

FIG. 5 is a cross-sectional view of the semiconductor device in accordance with the first embodiment, and is an enlarged view of FIG. 3. As illustrated in FIG. 5, the side face of the gate electrode 26 is inclined by an angle θ against the vertical direction (the Z direction). The widths Wa to Wd of the channel layers 14a to 14d decrease at farther distances from the substrate 10. The widths Wa to Wd of the channel layers 14a to 14d are widths in the Y direction in the 2DEGs 17a to 17d contributing mainly to the conduction. The heat generated in each of the channel layers 14a to 14d is released mainly from the substrate 10. Therefore, the heat generated in the channel layer 14d, which is farther from the substrate 10, is difficult to be released. Thus, the width Wd of the channel layer 14d, which is farther from the substrate 10, is made to be narrower than the width Wa of the channel layer 14a, which is closer to the substrate 10. This makes the amount of current in the channel layer 14d less than the amount of current in the channel layer 14a. Thus, the amount of heat generation in the channel layer 14d becomes lower than the amount of heat generation in the channel layer 14a. Hence, the heat can be efficiently released from the substrate 10.

The amount of current in each of the channel layers 14a to 14d is proportional to the two-dimensional electron concentration of the corresponding one of the 2DEGs 17a to 17d×the electron mobility in the corresponding one of the 2DEGs 17a to 17d×the corresponding one of Wa to Wd. In the 2DEGs 17a to 17d, the electron mobilities are substantially the same. When it is considered that the two-dimensional electron concentrations are substantially the same among the 2DEGs 17a to 17d, the amounts of currents in the channel layers 14a to 14d are substantially proportional to the widths Wa to Wd, respectively. In the case that the two-dimensional electron concentration of the 2DEG 17a is different from the two-dimensional electron concentration of the 2DEG 17d, the two-dimensional electron concentration of the 2DEG 17d×Wd is preferably less than the two-dimensional electron concentration of the 2DEG 17a×Wa.

When a low voltage is applied to the gate electrode 26, a depletion layer 58a in the semiconductor layer 12 expands to a depletion layer 58b as indicated by arrows 57. The respective leading end faces of the depletion layer 58a and the depletion layer 58b are parallel to the side face of the gate electrode 26 inclined by an angle θ against the vertical direction (the Z direction). Thus, the threshold voltage of the channel layer 14d having a narrower width Wd in the Y direction is shallower than the threshold voltage of the channel layer 14a having a wider width Wa. That is, the current will not flow unless a positively larger voltage is applied (or when the same voltage is applied in the case that the depletion layer does not expand so much, the amount of current flowing through the channel layer 14d with a narrower width Wd in the Y direction becomes less than the amount of current flowing through the channel layer 14a with a wider width Wa in the Y direction). As an example, when the width of the channel layer decreases from 245 nm to 195 nm by 50 nm, the threshold voltage shallows by 2 V. When a high-power high-frequency signal is input to the gate electrode 26, the period during which the channel layer 14d with a shallower threshold voltage is ON (the period during which the current flows) is short, while the period during which the channel layer 14a with a deeper threshold voltage is ON is long. As a result, the amount of heat generation in the channel layer 14d becomes lower than the amount of heat generation in the channel layer 14a. Therefore, the heat can be efficiently released from the substrate 10.

Even in the case that the side face of the gate electrode 26 is not inclined (the angle θ=0°) against the vertical direction (the Z direction), it is conceivable to arrange the gate electrodes 26 so that there are sections where the distance between the adjacent gate electrodes 26 is longer and sections where the distance between the adjacent gate electrodes 26 is shorter along the Y direction. In such an arrangement, it is possible to adjust the current value in the section where the distance between the adjacent gate electrodes is shorter to be the value different from the current value in the section where the distance is longer (adjust the current value in the section where the distance is shorter to be lower than the current value in the section where the distance is longer) even at the same bias voltage. However, it is possible to cause the amount of heat generation to be large or small depending on the positions, but the heat generated in the position of each of the gate electrodes 26 becomes unbalanced, which may hinder the efficient heat release from the substrate 10. In the semiconductor device in accordance with the first embodiment, the side faces of the gate electrodes are inclined to adjust the threshold voltage while the distances between the adjacent gate electrodes 26 are kept uniform. Thus, the heat is efficiently released from the substrate 10 while the amounts of heat generation from the gate electrodes 26 depending on the positions in the Y direction are equalized.

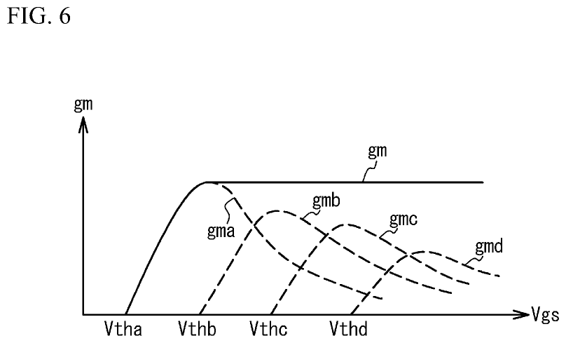

FIG. 6 schematically illustrates transconductances gma to gmd in the respective channel layers 14a to 14d in the first embodiment. The horizontal axis represents the voltage Vgs of the gate electrode 26 with respect to the source electrode 22, and the vertical axis represents the transconductance gm. As described above, the relationship among the respective widths Wa to Wd of the channel layers 14a to 14d is Wa>Wb>We>Wd. Therefore, as illustrated in FIG. 6, the relationship among the respective threshold voltages Vtha to Vthd in the channel layers 14a to 14d is Vtha<Vthb<Vthc<Vthd. The relationship among the respective transconductances gma to gmd of the channel layers 14a to 14d is gma>gmb>gmc>gmd. The sum gm of gma to gmd of the channel layers 14a to 14d corresponds to the gm of the semiconductor device. The transconductance gm becomes flatter with respect to Vgs. As the change in gm with respect to Vgs increases, the strain is likely to be larger. In the first embodiment, the change in gm with respect to Vgs is small, and therefore, the strain can be reduced.

### First Variation of the First Embodiment

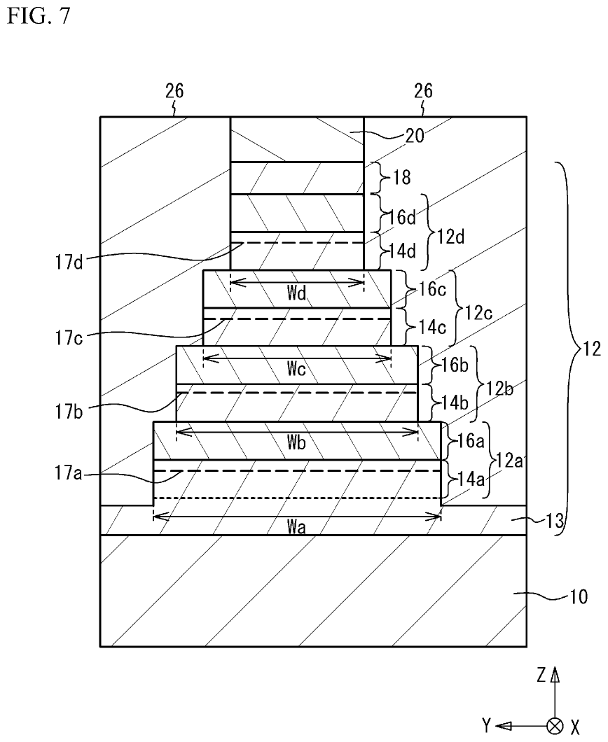

FIG. 7 is a cross-sectional view of a semiconductor device in accordance with a first variation of the first embodiment. As illustrated in FIG. 7, the side faces of the gate electrodes 26 are not inclined, and the width of the channel layer 14a in the Y direction and the width of the barrier layer 16a in the Y direction are substantially the same. Similarly, the width of the channel layer 14b in the Y direction and the width of the barrier layer 16b in the Y direction are substantially the same, the width of the channel layer 14c in the Y direction and the width of the barrier layer 16c in the Y direction are substantially the same, and the width of the channel layer 14d in the Y direction and the width of the barrier layer 16d in the Y direction are substantially the same. The relationship among the respective widths Wa to Wd of the channel layers 14a to 14d is Wa >Wb>Wc>Wd. Other structures are the same as those of the first embodiment, and the description thereof is thus omitted.

### Second Variation of the First Embodiment

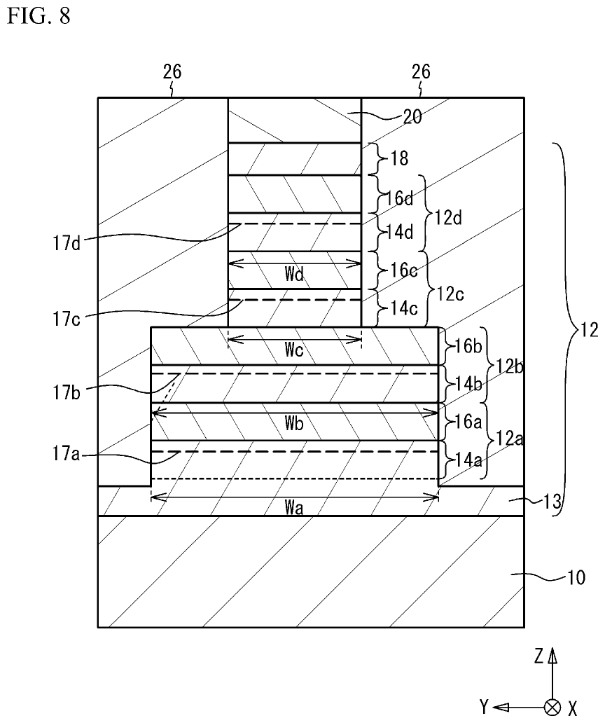

FIG. 8 is a cross-sectional view of a semiconductor device in accordance with a second variation of the first embodiment. As illustrated in FIG. 8, the side faces of the gate electrodes 26 are not inclined, the widths Wa and Wb of the channel layers 14a and 14b are substantially the same, and the widths Wc and Wd of the channel layers 14c and 14d are substantially the same. In other words, Wa=Wb>Wc=Wd. Other structures are the same as those of the first embodiment and the first variation of the first embodiment, and the description thereof is thus omitted.

### Third Variation of the First Embodiment

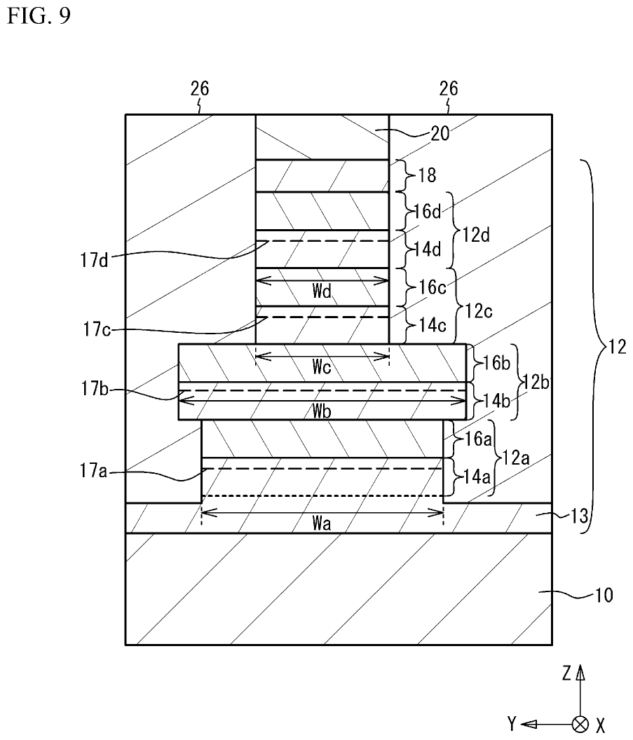

FIG. 9 is a cross-sectional view of a semiconductor device in accordance with a third variation of the first embodiment. As illustrated in FIG. 9, the side faces of the gate electrodes 26 are not inclined, the width Wa of the channel layer 14a is narrower than the width Wb of the channel layer 14b, and is wider than the widths Wc and Wd of the channel layers 14c and 14d. In other words, Wb>Wa>Wc=Wd. Other structures are the same as those of the second variation of the first embodiment, and the description thereof is thus omitted.

In the first embodiment and the variations thereof, the width Wd between the two adjacent gate electrodes in the channel layer farther from the substrate 10 (e.g., the channel layer 14d farthest from the substrate 10) of arbitrary two channel layers of the channel layers 14a to 14d is narrower than the width Wa between the two adjacent gate electrodes 26 in the channel layer closer to the substrate 10 (e.g., the channel layer 14a closest to the substrate 10). Because of this structure, the amount of heat generation in the channel layer 14d becomes lower than the amount of heat generation in the channel layer 14a. This allows the heat to be released from the substrate 10 efficiently.

In the first embodiment and the first and second variations thereof, in the case that the channel layers include three or more channel layers, in each pair of the adjacent channel layers of the channel layers 14a to 14d, the width of the channel layer farther from the substrate 10 is equal to or less than the width of the channel layer closer to the substrate 10. That is, Wa>Wd and Wa≥Wb≥Wc≥Wd. This allows the heat to be released from the substrate 10 more efficiently.

As in the first embodiment and the first variation thereof, in each pair of the adjacent channel layers, the width of the channel layer farther from the substrate 10 is narrower than the width of the channel layer closer to the substrate 10. That is, Wa>Wb>Wc>Wd. This allows the heat to be released from the substrate 10 more efficiently.

As in the first embodiment, the side faces of the two adjacent gate electrodes 26 are inclined against the stack direction of the channel layers 14a to 14d. This makes it easy to achieve Wa>Wb>Wc>Wd as illustrated in FIG. 4A to FIG. 4D. In addition, the coverage of the gate electrode 26 on the semiconductor layer 12 is improved. The side face of the gate electrode 26 may be flat or curved.

The width Wd in the uppermost channel layer 14d is equal to or less than 0.9 times the width Wa in the lowermost channel layer 14a. Because of this structure, the amount of heat generation in the channel layer 14d becomes lower than the amount of heat generation in the channel layer 14a. The width Wd is preferably equal to or less than 0.8 times the width Wa, more preferably equal to or less than 0.7 times the width Wa. The width Wa−the width Wd is preferably 10 nm or greater, more preferably 20 nm or greater, further preferably 50 nm or greater. The width Wa−the width Wd is preferably 200 nm or less, more preferably 150 nm or less. The inclination angle θ of the line (the plane) connecting the ends of the channel layers 14a and 14d with respect to the Z direction is preferably 5° or greater, more preferably 10° or greater, further preferably 15° or greater.

Too small width Wd compared with the width Wa makes the total amount of current flowing through all channel layers 14a to 14d small. Therefore, the width Wd is preferably equal to or greater than 0.3 times the width Wa, more preferably equal to or greater than 0.4 times the width Wa. The width Wa−the width Wd is preferably 200 nm or less, more preferably 150 nm or less. The inclination angle θ of the line (the plane) connecting the ends of the channel layers 14a and 14d with respect to the Z direction is preferably 40° or less, more preferably 30° or less.

Too large width Wa makes the control of the drain current difficult. From this point of view, the width Wa is preferably 1000 nm or less, more preferably 500 nm or less. Too small width Wa makes the drain current small. From this point of view, the width Wa is preferably 100 nm or greater, more preferably 200 nm or greater.

As in the first embodiment and the first variation thereof, in the case of Wa>Wb>We>Wd, the ratio of the width of the channel layer closer to the substrate 10 of the adjacent channel layers to the width of the channel layer opposite from the substrate 10 of the adjacent channel layers, i.e., Wb/Wa, Wc/Wb, and Wd/Wc are preferably 0.98 or less, more preferably 0.95 or less. The ratios Wb/Wa, Wc/Wb, and Wd/Wc are preferably 0.8 or greater, more preferably 0.85 or greater.

To increase the drain current, the number N of the channel layers 14a to 14d to be stacked is preferably three or greater, more preferably four or greater. To improve the heat release performance of the channel layer farthest from the substrate 10, the number N of layers is preferably 10 or less. The thickness T between the lowermost channel layer 14a and the uppermost channel layer 14d is preferably 50 nm or greater, and preferably 300 nm or less.

### Fourth Variation of the First Embodiment

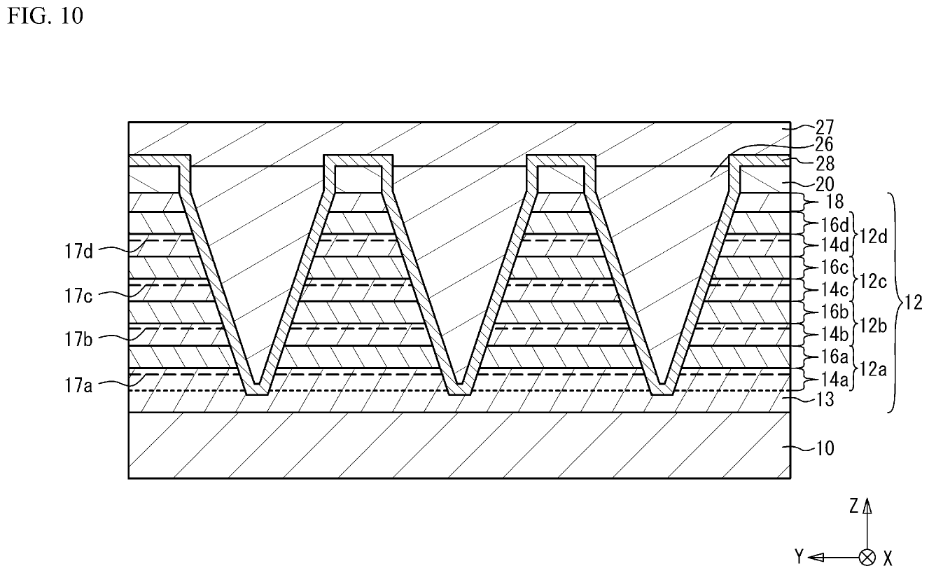

FIG. 10 is a cross-sectional view of a semiconductor device in accordance with a fourth variation of the first embodiment. As illustrated in FIG. 10, in the fourth variation of the first embodiment, an insulating film 28 is provided between the semiconductor layer 12 and the gate electrodes 26. The insulating film 28 is, for example, an inorganic insulating film such as an aluminum oxide film, a silicon oxide film, a silicon nitride film, a hafnium oxide film, or a silicon hafnium oxide film, and is an oxide film or a nitride film. The insulating film serves as a gate insulating film. Other structures are the same as those of the first embodiment, and the description thereof is thus omitted.

As in the first embodiment and the first to third embodiments thereof, the gate electrodes 26 may form Schottky junction with the semiconductor layer 12. This allows the heat generated in the channel layers 14a to 14d to be released through the gate electrodes 26.

As in the fourth variation of the first embodiment, the metal insulator semiconductor (MIS) structure in which the insulating film 28 is provided between the gate electrode 26 and the semiconductor layer 12 may be employed. In this case, the heat generated in the channel layer 14d is difficult to be released through the gate electrodes 26. Therefore, the width Wd of the channel layer 14d is preferably made to be narrower than the width Wa of the channel layer 14a.

Although the embodiments of the present invention have been described in detail, it is to be understood that the various change, substitutions, and alterations could be made hereto without departing from the spirit and scope of the invention.

What is claimed is:

1. A semiconductor device comprising:
a substrate;
a semiconductor layer that is provided on the substrate and includes channel layers that are stacked;
a source electrode and a drain electrode that are electrically connected to the channel layers; and
gate electrodes that are provided between the source electrode and the drain electrode, are arranged in a direction intersecting with a direction from the source electrode to the drain electrode, and are embedded in the semiconductor layer so as to extend from a top face of the semiconductor layer to at least a channel layer closest to the substrate,
wherein a width between two adjacent gate electrodes of the gate electrodes in a channel layer farther from the substrate of two channel layers of the channel layers, is narrower than a width between the two adjacent gate electrodes in a channel layer closer to the substrate of the two channel layers.

2. The semiconductor device according to claim 1,
wherein the channel layers include three or more channel layers, and
wherein in each pair of adjacent channel layers of the channel layers, a width between the two adjacent gate electrodes in a channel layer farther from the substrate is equal to or less than a width between the two adjacent gate electrodes in a channel layer closer to the substrate.

3. The semiconductor device according to claim 1,
wherein the channel layers include three or more channel layers, and
wherein in each pair of adjacent channel layers of the channel layers, a width between the two adjacent gate electrodes in a channel layer farther from the substrate is narrower than a width between the two adjacent gate electrodes in a channel layer closer to the substrate.

4. The semiconductor device according to claim 1, wherein side faces of the two adjacent gate electrodes are inclined against a stack direction of the channel layers.

5. The semiconductor device according to claim 1, wherein a width between the two adjacent gate electrodes in a channel layer farthest from the substrate among the channel layers is equal to or less than 0.9 times a width between the two adjacent gate electrodes in a channel layer closest to the substrate among the channel layers.

6. The semiconductor device according to claim 1, wherein the semiconductor layer has an energy of a bottom of a conduction band higher than energies of bottoms of conduction bands of the channel layers, and includes barrier layers stacked on the channel layers, respectively.

7. The semiconductor device according to claim 1, wherein the gate electrodes are in Schottky junction with the semiconductor layer.

8. The semiconductor device according to claim 1, further comprising an insulating film provided between the gate electrodes and the semiconductor layer.
